(19) United States
(12) Patent Application Publication
(10) Pub. No.: US 2009/0038683 A1
(43) Pub. Date: Feb. 12, 2009

(54) Method and Apparatus for Patterning a Conductive Layer, and a Device Produced Thereby

(76) Inventors: Harald Walter, Horgen (CH); Tilman Beierlein, Kilchberg (CH)

Correspondence Address: JoAnn Villamizar;Ciba Corporation/Patent Department, 540 White Plains Road, P.O. Box 2005, Tarrytown, NY, 10591, US

(21) Appl. No.: 12/084,749

(22) PCT Filed: Nov. 14, 2006
(86) PCT No.: PCT/IB2006/003995

§ 371 Date: May 8, 2008

(30) Foreign Application Priority Data
Nov. 14, 2005 (GB) 0523163.4

(51) Int. Cl. H01L 51/00; H01L 51/40; H01J 9/24; B44B 5/00; H01J 1/63; H01L 51/05

(52) U.S. Cl. 136/263; 438/82; 445/49; 313/504; 438/99; 257/40; 101/3.1; 257/E51.005; 257/E51.012

(57) ABSTRACT

A device is fabricated by a method in which a conductive layer or layer stack is formed over a compressible layer or layer stack, and contacted with an embossing tool. Raised portions of the embossing tool compress the compressible layer or stack and countersink the conductive layer or stack into the compressible layer or stack.

### FIELD OF THE INVENTION

The invention relates to the production of organic devices in general and is more particularly related to the patterning of conductive layers used in such organic devices like e.g. organic light emitting devices (OLEDs), organic field effect transistors (OFETs) or organic photocells.

1. Background of the Invention

The rapid development of organic device technology increases the need for fast and cheap but reliable methods for the deposition of the desired layers as well as for the patterning of the layers, especially of the conductive layers. Methods for production of large areas are needed. Roll-to-roll processes with polymeric substrates are a promising approach. Due to the low stability of the organic semi-conducting and conducting materials against oxygen and water for most applications good barrier properties of the substrate are needed. Therefore often barrier coatings are deposited on polymeric substrates prior to the deposition of the layers of the organic devices. To keep these barrier properties the patterning process must be carried out in an adequate manner. Especially permanent deformation of the substrate has to be avoided. Up to now there is a lack of patterning methods which address all the points mentioned above.

2. State of the Art

For the patterning of layers or layer stacks in organic devices several techniques are available. Etching of metal or transparent conductive oxide layers is one of them. First of all a protective layer, a so-called resist, is deposited on the layer to be patterned. The desired pattern is then created in the resist layer e.g. by photolithography followed by a development step. The pattern can be transferred in the layer that is to be patterned by a wet or dry etching step which removes the unprotected areas. After the etching step the residual resist must be removed. The big advantage of this technique is the high resolution of the process (down to 65 nm). On the other hand the multiple steps of the process make it very slow and costly. Further the etching chemistry or the plasma of the dry etching process is critical for many organic materials as well as for polymeric substrates and the barrier coatings on top of them. Thus this technique is not well suitable for roll-to-roll production.

Printing processes are capable of producing patterned polymeric layers. Even conducting polymers like PEDOT:PSS can be printed with high speed in roll-to-roll processes e.g. by gravure printing. Mixtures containing conducting particles like indium tin oxide (ITO) or metal nanoparticles are likewise possible. The drawback of the printing approach is the limitation of the resolution of the printing processes. Especially patterned layers of about 100 nm with a well defined thickness at the edges of the pattern are difficult to realise. Further the conductivity of printed conducting layers is still much lower compared to vacuum deposited ones.

Yet another method for patterning of layers is based on laser irradiation. By choosing the appropriate wavelength and power metal or transparent conductive oxide (TCO) layers can be partially removed from a substrate. Due to the heat that is introduced in the layer or layer stack and/or the substrate the method alters or damages the layers or the substrate. Furthermore the technique is up to now not fast enough to be implemented in a roll-to-roll process and the investment and thus the costs are rather high.

Patterned deposition by shadow masks is a fast and economic technique. It can be used in vacuum deposition techniques such as evaporation or sputtering even in a roll-to-roll coater. The drawback of this technique is the limited resolution of larger than 200 μm.

Methods for patterning of layers based on die-cutting and the like are described in the following applications.

The patent application WO 01/60589 A1 describes a method for microstructuring polymer-supported material, suitable for use, for instance, as light polarizers, transflectors, microelectrode arrays, or liquid-crystal alignment layers. Layers of the material are microstructured by pressing a master with desired features into the polymer support. The depth of the features of the master generally exceeds the thickness of the layer or layers and the master is sufficiently hard and capable of cutting through the layers into the polymer substrate. The method is well suited for the mentioned applications but is inapplicable for patterning of conductive layers used in organic devices due to the deformation of the substrate.

In the patent application US2005/0071969 A1 a method for solid state embossing of polymer devices is described. It comprises depositing layers of conducting, semiconducting and/or insulating polymer by solution processing and direct printing and embossing microgrooves in the multilayer structure. This patent application focuses on embossing of complex organic multilayer devices such as vertical polymer thin-film transistors (TFT). The described method does not solve the problem of damaging the substrate by cutting through the layer or layers. Further no solution is provided for the problem of damaging the substrate and/or the deposited conductive layer due to the material flow during the embossing step.

The patent application US2002/0094594 A1 discloses a method for patterning organic thin film devices using a die. It comprises coating a substrate with a first organic layer, followed by an electrode layer. Then a patterning die is pressed onto the electrode layer. This die is prepared such that the portions of the electrode layer which are in contact with the die stick to the die and thus are removed together with the die. A drawback of this patent application is that before the die can be reused it must be cleaned in an additional step. This slows down the speed of the process and increases the costs. For roll-to-roll applications this additional cleaning step is critical. Further the first organic layer must possess a weaker adhesion to the electrode layer than between the die and the electrode layer. This release function lowers the stability of the layer setup distinctly and limits the possible material combinations.

In the patent application WO2004/111729 A1 a method and an apparatus for manufacturing electronic thin-film components is described. It comprises the following steps. A conductive layer is formed directly on a dielectric substrate. Galvanically separated conductive areas are formed by exerting on the conductive layer a machining operation based on die-cutting, wherein the relief of the machining member causes a permanent deformation on the substrate. On top of this patterned electrode layer it is then possible to form a desired electronic thin-film component by depositing the required layers. Due to the permanent deformation of the substrate critical stress is induced in the conductive layer during the patterning process. Further the barrier properties of the substrate will be degraded.

A method for structuring layers of organic circuits by pressing an embossing tool at a defined temperature and with a defined pressure in an organic layer is disclosed in the patent application WO2005/006462. The structuring is performed in such a way that the organic layer keeps the structuring permanently. The main goal of this patent application is to provide a time-efficient method to structure an isolating organic layer between conducting or semi-conducting organic layers to get an interlayer connection.

### DESCRIPTION OF THE INVENTION

An object of the present invention is to eliminate at least some of the drawbacks of the state of the art.

The invention provides a method of patterning layers of organic devices. It also provides organic devices with layers patterned according to the method as defined in the appended independent claims. Preferred, advantageous or alternative features of the invention are set out in dependent claims.

In a first aspect the present invention provides a method of patterning a conductive layer or a layer stack comprising at least one conductive layer in which between the layer or layer stack and the substrate there is a compressible spacer layer or a spacer layer stack comprising at least one compressible layer.

In a second aspect the invention provides organic devices with at least one conductive layer which is patterned according to the claimed method.

### Embodiments of the invention are described hereinafter with reference to the following schematic drawings.

FIG. 1 shows a schematic drawing of a first patterning method embodying the invention,

FIG. 2 shows a schematic drawing of a second patterning method embodying the invention,

FIG. 3 shows a schematic drawing of a third patterning method embodying the invention,

FIG. 4 shows microscope images of embossed samples,

FIG. 5 shows a schematic drawing of still another patterning method embodying the invention,

FIG. 6 shows an OLED device made by a method embodying the invention, and

FIG. 7 shows a transistor made by a method embodying the invention.

Organic devices such as organic light emitting devices (OLEDs), organic field effect transistors (OFETs) or organic photocells, possess one or more conductive layers in the layer setup. E.g. the simplest layer setup of an OLED is a three layer setup with a transparent anode layer, the light emitting layer and a cathode layer. To obtain the desired function of the devices the conductive layers need to be patterned in an appropriate manner. The central point of this invention is to pattern the conductive layer or layers by embossing, whereas between the substrate and the first conductive layer there is a compressible spacer layer or a spacer layer stack with at least one such compressible layer. The thickness of the compressible layer shrinks at the embossed areas due to the pressure applied by the embossing tool (see FIG. 1). The conductive layer or the layer stack comprising at least one conductive layer is disjoint at the edges of the embossed areas and countersunk in the compressible layer. For this the compressible layer should be more compressible than the other layers. If the parameters of the embossing step are chosen adequately only the above mentioned layers are deformed permanently whereas the substrate is not permanently deformed by the process. Especially barrier coatings which are deposited to enhance the barrier properties of polymeric substrates can be kept undamaged (see FIG. 2).

### Material Substrate:

Suitable substrates (1) for the organic devices are glass, polymer, especially polymeric foil, paper or metal. Flexible substrates are well suited for roll-to-roll processes. The substrate can be for example a flexible polymer foil like acrylonitrile butadiene styrene ABS, polycarbonate PC, polyethylene PE, polyetherimide PEI, polyetherketone PEK, poly(ethylene naphthalate) PEN, poly(ethylene therephtalate) PET, polyimide PI, poly(methyl methacrylate) PMMA, poly-oxy-methylene POM, mono oriented polypropylene MOPP, polystyrene PS, polyvinyl chloride PVC and the like. Other materials like paper (weight per area 20-500 g/m², preferably 40-200 g/m²), metal foil, (for example Al-, Au-, Cu-, Fe-, Ni-, Sn-, steel-foil etc.), especially surface modified, coated with a lacquer or polymer, are suitable too. The substrate can be coated with a barrier layer (4) or a barrier layer stack (5) to increase the barrier properties (J. Lange and Y. Wyser, “Recent Innovations in Barrier Technologies for Plastic Packaging—a Review”, Packag. Technol. and Sci. 16, 2003, p. 149-158). E.g. inorganic materials like SiO₂, Si₃N₄, SiOₓN_{y}, Al₂O₃, AlOₓN_{y} and the like are often used. They can be deposited e.g. in vacuum processes like evaporation, sputtering or chemical vapour deposition CVD, especially plasma enhanced CVD (PECVD). Other suitable materials are mixtures of organic and inorganic materials deposited in a sol-gel process. Such materials can even be deposited in a wet coating process like e.g. gravure printing. The best barrier properties at present are obtained by multilayer coatings of organic and inorganic materials as described in WO03/094256A2. In the following the term substrate shall denote substrates with and without barrier coatings.

### Material Compressible Layer:

Suitable materials for the compressible layer (2) are low density polymer like e.g. low density poly ethylene (LDPE) with a density of about 0.92 g/cc. Most isolating and conducting polymers possess densities >1.0 g/cc. E.g. Poly(methyl methacrylate) PMMA has a density of 1.19 g/cc, poly(styrene) PS of 1.05 g/cc, poly(carbonate) PC of 1.2 g/cc and poly(ethylene terephthalate) PET of 1.3-1.4 g/cc. The density of metals and TCOs is even distinctly higher. E.g. Aluminum (Al) has a density of 2.7 g/cc, Copper (Cu) of 8.96 g/cc, Silver (Ag) of 10.5 g/cc or Gold (Au) of 19.3 g/cc and tin doped indium oxide (ITO) of 7.14 g/cc. Thus the low density polymer possesses the lowest density of all materials in the organic device. Upon embossing such a compressible spacer layer is compressed leading to an increase in the density combined with a decrease in the layer thickness. A much better compressibility for the spacer layer is obtained by the use of meso- or nano-porous materials. E.g. sol-gel processed silica aerogel as described by Tsutsui et. al. (“Doubling Coupling-Out Efficiency in Organic Light-Emitting Devices Using a Thin Silica Aerogel Layer”, Adv. Mater. 13, 2001, p. 1149-2252) possess an index of refraction as low as 1.03 which is only possible if the majority of the volume of the layer is air or gas. This air or gas filled volume takes up the material upon embossing. Such porous layers can be produced by other techniques too. Inorganic oxides, e.g. silica or boehmite, in a mixture with a binder, like e.g. poly(vinyl alcohol) PVA or poly(vinylpyrrolidone) PVP, are capable of forming layer of high porosity and thus low density as described in the US2005/0003179 A1, EP1464511 A2 and the EP0614771 A1. In the mentioned documents the porous layer functions as an ink absorbing layer. As the conducting layer or the layer stack comprising at least one conducting layer is coated on top of the spacer layer (stack) a flat surface is advantageous. In most cases the porosity of the compressible meso- or nano-porous layer leads to a rough surface. To solve this problem a thin homogeneous and flat layer can be coated on top of the porous layer prior to the conducting layer or layer stack. This homogeneous layer can be made of inorganic dielectrics like SiO₂, Al₂O₃ and the like or of polymer like but not limited to PMMA, PS or PVA. Suitable and preferred thickness ranges for the layers in the spacer layer stack is:

| | suitable thickness | preferred thickness |
|---|---|---|
| compressible | 200 nm-50 μm | 1 μm-20 μm |
| layer d_{comp} | | |
| flat top | 0 nm-2 μm | 50 nm-500 nm |
| layer d_{flat} | | |

A further advantage of the porous layer is that due to the holes in the layer (similar to a sponge) residues of the embossed conducting layer can not stick well to the vertical walls. Thus shorts between the embossed and the not embossed parts of the conducting layers are less probable.

### Material Conducting Layer

The conductive layers (3) are often made of metal like e.g. Al, Cu, Ag or Au. The metal layers can be semitransparent (depending on the metal with a thickness of a few tenth of nanometers up to 50 nm) or opaque (thickness of >50 nm). Other suitable materials are transparent conductive oxides (TCO) like e.g. ITO, aluminium doped zinc oxide (AZO) or gallium doped zinc oxide (GZO). Typical thickness of such a TCO layer is in the range of 50 nm up to 150 nm. Due to a distinct increase of the stress in inorganic layers above a thickness of roughly 200 nm (depending on deposition method and parameter) typical values of the conducting layers are below that threshold. Organic conducting layers are e.g. made of polymers like Poly(styrene sulfonate) doped Poly(3,4-ethylenedioxythiophene) PEDOT/PSS, Poly(aniline) PANI or Polypyrrole. The conducting polymer layers possess the same typical thickness range as the TCO layers. Also a combination of above mentioned layers may serve as conductive layer, e.g. an ITO layer coated with a polymer where the latter acts as injection layer as well as buffer layer to avoid cracking of the ITO or at least for binding ITO particles during the embossing process.

### Embossing Tool:

The embossing tool (10) must be made of a material which is harder than the layers to be embossed. E.g. so called nickel shims are suitable. They are state of the art and widely used in the hologram manufacturing industry as well as in the CD/DVD production. If needed the structure size to be embossed can be down to a few tenth of nanometer. Such shims can be flat to emboss sheets or plane objects.

On the other hand they can be put around a roll for roll-to-roll embossing of flexible objects like polymeric foil or paper. To get the desired pattern in a nickel shim first of all this pattern is made in a master substrate by photolithography, e-beam lithography or another suitable technique. One possibility is to coat a flat glass substrate with a light sensitive polymer (a so called resist) of a certain thickness and illuminate it through a mask, e.g. a chromium mask, which possesses the pattern. Depending on the type of resist the illuminated pattern (positive resist) or the protected area (negative resist) can be removed in a development step. The thickness of the resist defines the height or depth of the pattern. By coating this patterned glass substrate with a conducting material, e.g. evaporated Nickel, Silver or Gold or sprayed Silver solution, a starting layer for the electroforming of the Nickel shim is deposited. After the electroforming step a first generation Nickel shim is obtained from which second and further generation shims can be made by additional electroforming steps. Another possible material for the embossing tool is hardened steel. The pattern can be transferred in this material class by diamond turning or other tooling techniques if the desired pattern is suitable for these techniques. Wet etching or dry etching techniques can be used likewise as described in the US2004/0032667 A1 which is incorporated herein by reference. The etching techniques are well suited for very small patterns, e.g. even subwavelength gratings are possible.

For organic devices the size of the pattern in the conducting layer varies at present from 5 μm×15 μm (matrix displays) up to a few cm² or more (logos). The width of the separator between adjacent pixels should be as small as possible. In current matrix displays it is about 3 μm.

In one embodiment of the described invention the width of the separators is defined by the width of the embossed pattern. If the embossed parts of the conducting layer are used in the device too, the separator is defined by the width of the embossed edge. This width of the edges depends on the height of the pattern as the walls of the pattern in the embossing tool are not perfectly vertical. Values of <20 μm are easily obtainable. In one embodiment of the invention the depth or height of the pattern hₚₐₜₜ in the embossing tool is smaller than the thickness d_{comp} of the compressible layer. Suitable values for hₚₐₜₜ are <25 μm, preferred values are <9 μm.

### Coating and Embossing Processes

The deposition of the compressible spacer layer or spacer layer stack can be done by several coating techniques. Low density polymers can be wet coated for example by spin-coating, by printing, especially flexo-printing, gravure printing, ink-jet-printing or screen-printing, by curtain or dip coating or by spraying. Porous spacer layer can be wet or vacuum coated. E.g. CVD processes are capable of forming porous silica layer if appropriate coating parameters are chosen. Other approaches use spin-, curtain- or cascade coating to deposit the porous layer. The latter two techniques are roll-to-roll processes and thus capable for large area production. Examples for the deposition of porous layers of inorganic oxides like silica and boehmite are described in EP1464511 A2 and EP0614771 A1.

The optional flat top layer can be deposited by several techniques. Top layers of inorganic materials like SiO₂ can be vacuum deposited by e.g. evaporation, sputtering or CVD. Sol-gel processes are likewise possible (M. Mennig et. al. “Interference multilayer systems on plastic foil by a wet-web-coating technique”, Proceedings of the 5^{th} International Conference on Coatings on Glass, p. 175). Organic top layers can be vacuum (PECVD) or wet coated. Again spin-coating, printing, especially flexo-printing, gravure printing, ink-jet-printing or screen-printing, curtain or dip coating or spraying are possible. In a preferred embodiment of the invention the flat organic top layer is coated on top of the porous spacer layer in the same process. This can be done e.g. by curtain- or cascade coating as described for example in the WO03/053597 A1. These processes are capable of coating more than ten layers of a multilayer stack in one step.

The conducting layer can be likewise deposited in wet- or vacuum processes. Metal layers are often evaporated or sputtered in large areas. E.g. for security holograms or packaging applications roll-to-roll vacuum coaters with a web speed of more than 10 m/sec are state of the art (see e.g. http://www.galileovacuum.com). TCOs are mostly sputter deposited, but evaporation is possible too, if the required conductivity is not too high. First attempts are made to coat TCO layers by wet coating techniques. E.g. a spin-coating process for the deposition of ITO is described by Al-Dahoudi and Aegerter (“Comparative study of transparent conductive In₂O₃:Sn (ITO) coatings made using a sol and a nanoparticle suspension” Proceedings of the 5^{th} International Conference on Coatings on Glass, p 585-592). Such TCO sol-gel or nanoparticle materials can be used in roll-to-roll coating techniques too. E.g. printing, especially gravure printing is a suitable method. Organic conducting layer can be deposited by several wet coatings techniques, like but not restricted to, spin-coating, printing, especially flexo-printing, gravure printing, ink-jet-printing or screen-printing, curtain or dip coating or spraying.

The embossing of the coated layers can be done in step by step machines or in roll-to-roll embossing machines. The former can be e.g. an EVG520HE semi-automated hot embossing system. It accepts substrates up to 200 mm. The stamps used can possess pattern sizes ranging from 400 nm to 100 μm (Nils Roos et. al., “Impact of vacuum environment on the hot embossing process”, SPIE's Microlithography 2003, Santa Clara, Calif., Feb. 22-28, 2003). One example of a roll-to-roll embossing machine is described on page 34 in the research activities in optoelectronics and electronics manufacturing report 2004 of VTT Electronics Finland (www.vtt.fi). This machine is capable of doing web gravure printing and web embossing in serial units. In general the applied pressure has to be adapted to the materials used in the layer stack, the web speed and the embossing temperature as well as the size and depth of the pattern to be embossed. The embossing can be done at room temperature or at elevated temperature (hot embossing). E.g. if a hard conducting material like ITO on top of a compressible porous spacer layer with an organic flat top layer needs to be patterned the stress in the conducting layer can be minimised by doing the embossing at a temperature above the glass transition temperature of the organic flat top layer.

After the embossing post treatments can be applied if necessary. E.g. plasma processes like oxygen plasma or argon plasma can be applied to remove residues of layers. Other post treatment possibilities are wet etching. E.g. an ITO etch solution (481 ml/l hydrochloric acid (32%), 38 ml/l nitric acid (65%) and 481 ml/l deionised water) can be used to remove ITO residues at the edges of the embossed areas to avoid possible shorts between the separated conducting areas. If an appropriate diluted concentration is chosen the needed conducting ITO areas are kept intact. A subsequent coating step of a polymer layer e.g. PEDOT/PSS could cover and repair possible cracks in the ITO layer.

The ability to do all deposition, patterning and (if necessary) post treatment steps in roll-to-roll processes enables the large area production of patterned conducting layers for organic devices at low costs.

### DESCRIPTION OF THE FIGURES

FIG. 1 shows a schematic drawing of a patterning method embodying the invention. A conducting layer (1) (e.g. ITO) on top of a compressible spacer layer (2) (e.g. LDPE) with a thickness of d_{comp} on top of a substrate (1) (e.g. PET) is embossed by an embossing tool (10) comprising pattern (100) with a height of hₚₐₜₜ. After embossing the spacer layer is compressed at the areas of protruding bars in the embossing tool.

FIG. 2 shows a schematic drawing of another patterning method embodying the invention. Hereby there is a spacer layer stack with a thick compressible layer (2) (e.g. porous silica) and a flat thin top coat (4) (e.g. PVA) between the conducting layer (3) (e.g. ITO) and the substrate (1) (e.g. PET). Again after embossing the compressible layer is compressed at the areas of protruding bars in the embossing tool.

FIG. 3 shows a schematic drawing of still another patterning method embodying the invention. The layer setup is the same as in FIG. 1. In this case the substrate possesses a barrier coating (5) (e.g. barix™ www.vitexsys.com). After embossing the multilayer barrier keeps its function.

FIG. 4 shows microscope images of embossed samples without and with a compressible spacer layer between a sputtered ITO layer and a PET substrate. For the latter a PET substrate of 100 μm thickness was coated with a double layer system consisting of a compressible porous silica layer and a flat top PVA layer (see FIG. 2). The thickness of the porous silica layer is about 25 μm and the thickness of the PVA layer 120 nm. On top of this spacer layer stack a 110 nm thick ITO conducting layer was deposited by sputtering at room temperature. The target composition was 90% In₂O₃ and 10% SnO₂. The bare PET substrate was coated in the same sputtering process. Both samples were embossed with a nickel shim at 120° C. and with a pressure of 63 kg/cm² (or 620N/cm²) for 10 min and cooled down under pressure for additional 10 minutes. The bars of the pattern in the nickel shim possess a height of 15 μm and thus are distinctly smaller than the thickness of the compressible layer stack. The width of the bars varies from 25 μm up to 800 μm. The embossed patterns are on one hand squares of 5×5 mm² and 10×10 mm² with different bar width and on the other hand 10 mm long bars of 100 μm width and varying distance from 300 μm up to 3 mm. FIG. 4 shows the corner of the square with a bar width of 150 μm. As can be seen the ITO layer of the sample without the compressible spacer layer stack is crazed, or slivered, all over. The ITO layer on top of the compressible spacer layer stack is intact. Just a few cracks, or rifts, are visible at the corner. These rifts are not present at embossed squares with thinner bars. The sample with the ITO deposited directly on the PET shows shorts between the inner and the outer ITO area of the embossed square. The resistivity is >20 MΩ for the sample with the compressible spacer layer stack. Furthermore the embossed bars with 100 μm width show no cracks or slivering (crazing) even at a distance of 300 μm.

FIG. 5 shows a schematic drawing of another patterning method embodying the invention. Two conducting layers (31,32) (e.g. ITO) separated by an isolating layer (40) (e.g. SiO₂) are deposited on top of a compressible spacer layer (2) (e.g. porous silica) and embossed such that the desired pattern forms. The patterned substrate is homogeneously coated with a thin organic semiconductor layer (50) (e.g. poly(3-hexylthiophene, P3HT) followed by thin isolating layer (60) such that both layers cover the walls of the embossed pattern. The embossed holes are then filled with a conducting material (70). Such a setup can is act as a transistor with a channel length defined by the thickness of the isolating layer between the two conducting layers and the angle of the embossed walls.

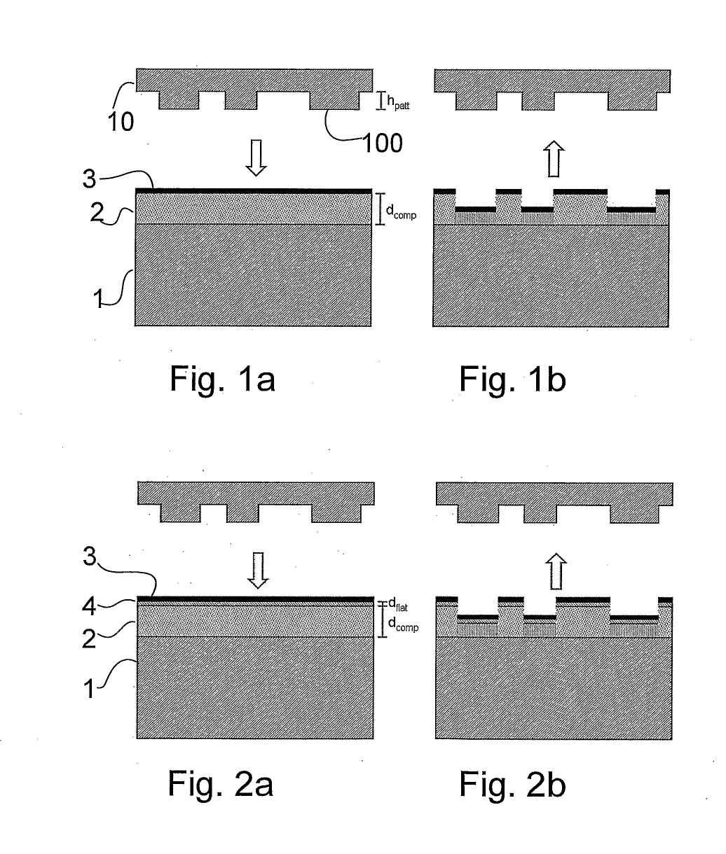

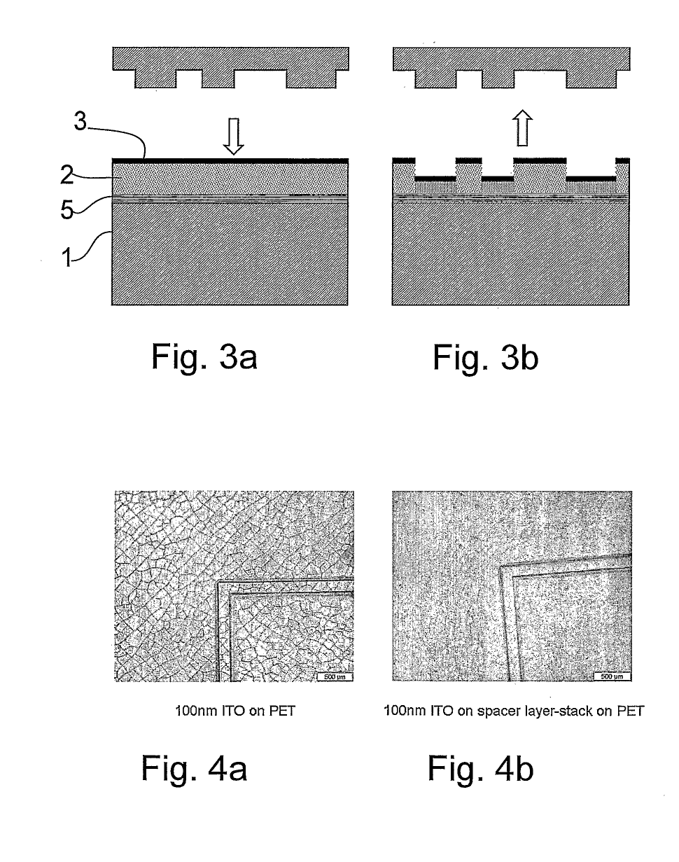

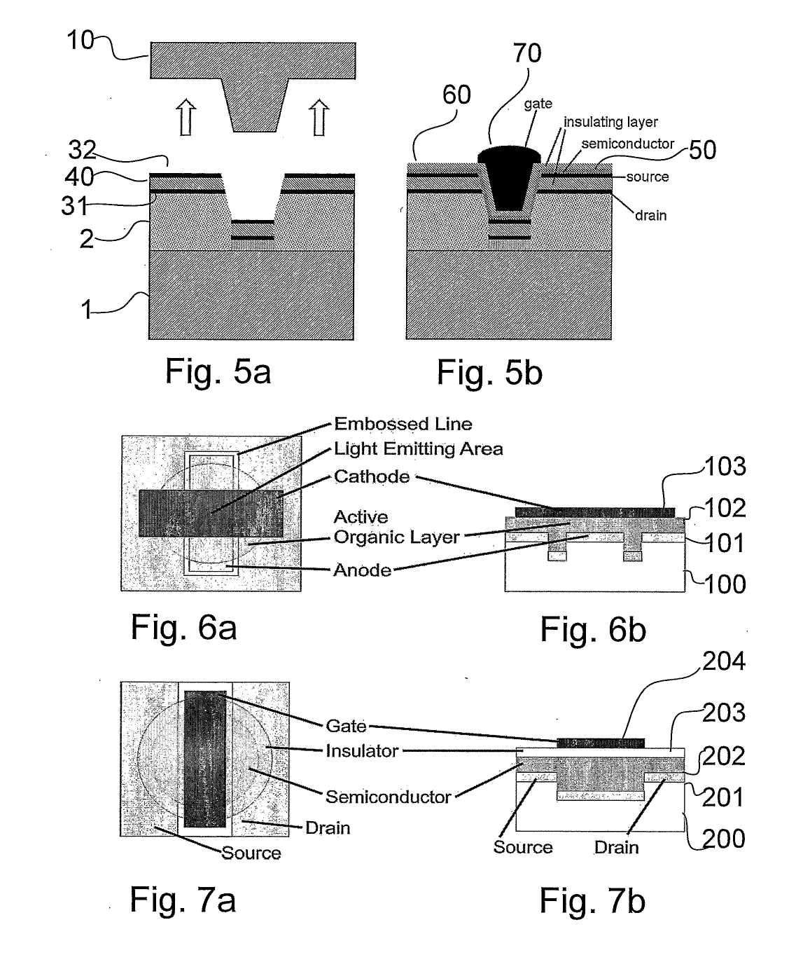

### EXAMPLES

The following examples illustrate the invention. The invention is not limited to these examples.

### OLED:

A 100 nm thick ITO anode is patterned on a compressible spacer layer stack analogously as explained in the description of FIG. 4. Prior to the deposition of the spin-coat layer the sample was treated with air plasma for 2 minutes (Harrick Plasma Cleaner PDC-002) . Solutions of tris (2,2′bipyridyl) ruthenium(II) hexafluorophosphate ([Ru(bpy)₃] (PF₆)) and poly(methyl methacrylate) (PMMA) with a molecular weight of 120000 g/mol dissolved in acetronitrile are prepared. Two solutions of ([Ru(bpy)₃] (PF₆) 40 mg/ml and PMMA 25 mg/ml are mixed in the ratio of 3:1 by volume. Films are prepared by spin-coating with 1500 rpm resulting in film thicknesses of approximately 120 to 200 nm. The devices are dried under nitrogen atmosphere on a hotplate at 100° C. for one hour. Without exposure to air the devices are loaded into a vacuum chamber with a base pressure of less than 10⁻⁷ mbar. A 200 nm thick Ag electrode is evaporated on top the devices and patterned via shadow mask. For device characterization a voltage of about 2.5 to 5 V is applied to the bottom and the top electrode. The overlap of the bottom electrode and the top electrode defines the light emitting area as it is shown in FIG. 6.

### Transistor:

Source and drain electrodes consisting of 50 nm sputter deposited Au on top of a compressible layer stack are patterned analogously to the method in the description of FIG. 4. Typical channel lengths and widths are 50 μm and 500 μm, respectively. In a top gate structure the semi-conducting polymer, e.g. P3HT is spun on top of the embossed structure. Afterwards an insulating layer e.g. PMMA is spin-coated as the gate dielectrics. A top metal gate contact is evaporated on top of this structure and patterned via shadow mask as shown in FIG. 7.

### Solar Cell

The same bottom ITO electrode pattern and method as described for fabricating OLEDs (see FIG. 6) is used to fabricate organic solar cells or photodiodes. In this case a multilayer is fabricated on top of this patterned substrate. First PEDOT/PSS is spin-coated on the substrate resulting in a layer of about 60 nm. This layer is dried for 15 min on a hotplate at 200° C. A polymer blend consisting of P3HT and a C60 derivative (PCBM) dissolved in dichlorobenzene with a ratio of 1:3 is spin-coated on top. The layer thickness of this layer is in the range of 50 to 250 nm. The device is dried under dry nitrogen for 30 minutes on a hotplate with 120° C. A cathode is evaporated on top of this structure analogously as mentioned above for the fabrication of OLEDs. Upon irradiation of the solar cell a current can be measured in a wire connecting the two electrodes.

1. A method for patterning a conductive layer, or a conductive layer stack comprising at least one conductive layer, comprising the following steps:
forming a compressible layer, or a compressible layer stack comprising at least one compressible layer, over a substrate; and
forming the conductive layer or stack over the compressible layer or stack;
to form a coated substrate, and
contacting the coated substrate with an embossing tool such that a predetermined pattern is formed in the conductive layer or stack, in which at embossed areas the compressible layer or stack is compressed and the conductive layer or stack countersinks in the compressible layer or stack.

2. A method according to claim 1, in which the conductive layer in the embossed areas is disjoint from the conductive layer in adjacent unembossed areas.

3. A method according to claim 1, in which the compressible layer or stack is more compressible than other layers in the coated substrate.

4. A method according to claim 1, in which the compressible layer or stack comprises a low density polymer.

5. A method according to claim 1, in which the compressible layer or stack comprises a porous material.

6. A method according to claim 1, in which a flat layer is formed over the compressible layer or stack before formation of the conductive layer or stack.

7. A method according to claim 1, in which the thickness of the compressible layer or stack is between 200 nm and 50 μm.

8. A method according to claim 7, in which the thickness of the compressible layer or stack is between 1 μm and 20 μm.

9. A method according to claim 1, in which residues or edges of the embossed conducting layer or stack substantially do not adhere or stick to adjacent walls of the compressible layer or stack.

10. A method according to claim 1, in which the conducting layer or stack comprises a metal.

11. A method according to claim 1, in which the conducting layer or stack comprises an organic conductor.

12. A method according to claim 1, in which the conducting layer or stack comprises an inorganic conductor.

13. A method according to claim 1, in which the height of a patterned portion of the embossing tool is less than 25 μm.

14. A method according to claim 1, in which the step of embossing is carried out in a step-by-step machine or in a roll-to-roll machine.

15. A method according to claim 1, in which the embossing step is done at elevated temperature.

16. A method according to claim 1, further comprising the step of carrying out a treatment after embossing, said step is selected from the group consisting of etching, coating and plasma processing.

17. A method according to claim 1, further comprising the step of depositing a conducting material in an embossed area of the conductive layer.

18. A method according to claim 1, further comprising the step of depositing an organic layer in an embossed area of the conductive layer or stack.

19. A method according to claim 1, further comprising the step of depositing a multilayer in an embossed area of the conductive layer or stack.

20. A method for patterning a conductive layer or a layer stack comprising at least one conductive layer, said method comprising the following steps:
coating a substrate with a compressible spacer layer or a spacer layer stack comprising at least one compressible layer
coating the conductive layer or the layer stack comprising at least one conductive layer on top of the spacer layer or the spacer layer stack
bringing the coated substrate in contact with a embossing tool such that the desired pattern are formed in the conductive layer whereas at the embossed areas the spacer layer or spacer layer stack is compressed and the conductive layer or the layer stack comprising at least one conductive layer countersinks in the spacer layer or spacer layer stack.

21. A device fabricated according to the method of claim 1.

22. An organic device, a transistor, a light emitting device or a photovoltaic device fabricated according to the method of claim 1.

23. A device comprising a conductive layer or stack formed over a compressible layer or stack, in which at least an area of the conductive layer is countersunk into a compressed area of the compressible layer or stack according to the method of claim 20.

24. An organic device, a transistor, a light emitting device or a photovoltaic device comprising a conductive layer or stack formed over a compressible layer or stack, in which at least an area of the conductive layer is countersunk into a compressed area of the compressible layer or stack according to the method of claim 20.

25. An embossing tool for use in a method according to claim 1.

26. A method for fabricating a device according to claim 1, substantially as described herein with reference to the drawings.

27. A device selected from the group consisting of an organic device, a transistor, a light emitting device and a photovoltaic device, substantially as described herein with reference to the drawings.

28. An embossing tool according to claim 25 substantially as described herein with reference to the drawings.

29. A method according to claim 4, in which the compressible layer or stack comprises a low density polymer with a density less than 1.0 g.cm⁻³.

30. A method according to claim 13, in which the height of a patterned portion of the embossing tool is less than 9 μm.

31. A method according to claim 17 for fabricating a transistor.

32. A method according to claim 18 for fabricating an organic light emitting diode (OLED).

33. A method according to claim 19 for fabricating a solar cell, photodiode, or other photovoltaic device.
